(19) United States
(12) Patent Application Publication
(10) Pub. No.: US 2025/0174492 A1
(43) Pub. Date: May 29, 2025

(54) INTERCONNECTION STRUCTURE HAVING AIR GAP

(71) Applicant: TAIWAN SEMICONDUCTOR MANUFACTURING COMPANY, LTD., Hsinchu (TW)

(72) Inventors: Shu-Yun KU, Hsinchu (TW); Chia-Chen LEE, Hsinchu (TW); Wei-Chen CHU, Hsinchu (TW); Chia-Tien WU, Hsinchu (TW); Hsin-Ping CHEN, Hsinchu (TW)

(73) Assignee: TAIWAN SEMICONDUCTOR MANUFACTURING COMPANY, LTD., Hsinchu (TW)

(21) Appl. No.: 18/523,286

(22) Filed: Nov. 29, 2023

(51) Int. Cl. H01L 21/768; H01L 23/522; H01L 23/528

(52) U.S. Cl. CPC H01L 21/7682; H01L 23/5226; H01L 23/528

(57) ABSTRACT

An interconnection structure includes a semiconductor substrate, an interlayer dielectric layer that is disposed over the semiconductor substrate, and a metal trench that is formed in the interlayer dielectric layer. The interlayer dielectric layer is formed with an air gap, and the metal trench is disposed over the air gap.

### BACKGROUND

The semiconductor integrated circuit (IC) industry has over the past decades experienced tremendous advancements and is still experiencing vigorous development. However, advances in IC design need to be accompanied by improvements in manufacturing in order to optimize device performance. As an example, interconnections between different layers of wires and associated dielectrics affect IC performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a sectional view illustrating an interconnection structure in accordance with some embodiments.

FIG. 2 is a flow chart illustrating a method for fabricating an interconnection structure in accordance with some embodiments.

FIGS. 3 through 13 are sectional views illustrating intermediate stages of the method for fabricating an interconnection structure in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

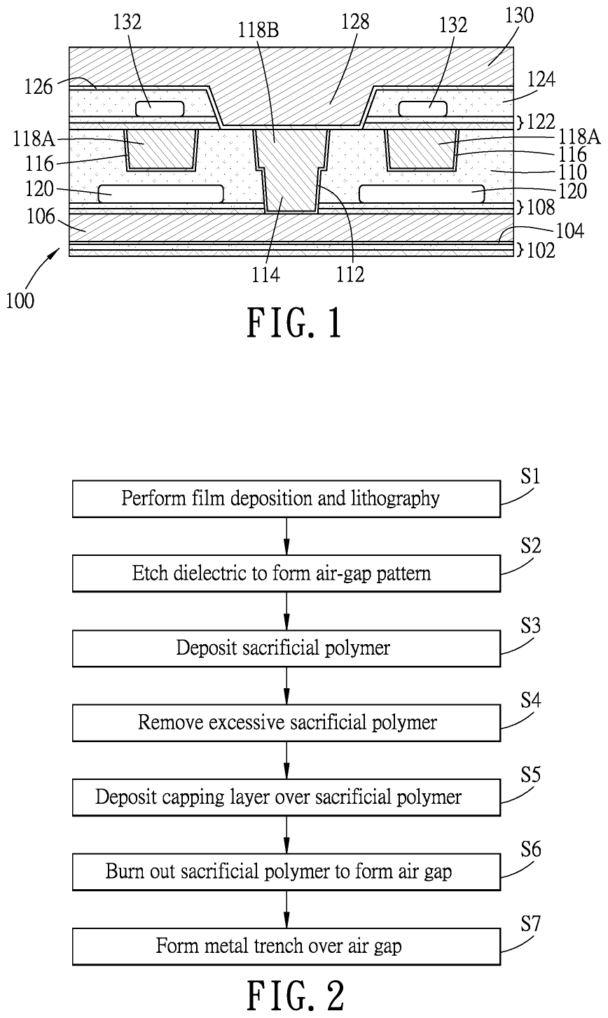

FIG. 1 illustrates a sectional view of an interconnection structure that has air gaps formed therein and that is formed over a substrate 100 in accordance with some embodiments. Air has a very low dielectric constant (approximating to 1), and thus is a superb low-k dielectric candidate for reducing capacitance under dimension scaling. The substrate 100 may be a bulk semiconductor substrate or a semiconductor-on-insulator (SOI) substrate, which may be doped (e.g., with a p-type or an n-type dopant) or undoped. In some embodiments, an SOI substrate includes a layer of a semiconductor material formed on an insulator layer. The insulator layer may be a buried oxide (BOX) layer, a silicon oxide layer or any other suitable layer. The insulator layer may be provided on a suitable substrate, such as silicon, glass or the like. The substrate 100 may be made of a suitable semiconductor material, such as silicon or the like. In some embodiments, the substrate 100 is a silicon substrate; and in other embodiments, the substrate 100 is made of a compound semiconductor such as silicon carbide, gallium arsenide, indium arsenide, indium phosphide or other suitable materials. In still other embodiments, the substrate 100 is made of an alloy semiconductor such as GaAsP, AlInAs, AlGaAs, GaInAs, GalnP, GaInAsP or other suitable materials.

In some embodiments, the substrate 100 includes various p-type doped regions and/or n-type doped regions, such as p-type wells, n-type wells, p-type source/drain features and/or n-type source/drain features (source/drain feature(s) may refer to a source or a drain, individually or collectively depending upon the context), formed by a suitable process such as ion implantation, thermal diffusion, a combination thereof, or the like. In some embodiments, the substrate 100 may include other functional elements such as resistors, capacitors, diodes, transistors, and/or the like. The transistors are, for example, field effect transistors (FETs), such as planar FETs and/or 3D FETs (e.g., FinFETs, GAAFETs). The substrate 100 may include lateral isolation features (e.g., shallow trench isolation (STI)) configured to separate various functional elements formed on the substrate 100 and/or various functional elements formed in the substrate 100.

In the illustrative embodiment, the substrate 100 includes an etch stop layer 102, a barrier layer 104, and a metal trench (or metal wire) 106 formed on top. In accordance with some embodiments, the etch stop layer 102 may be of either a multilayer structure (as shown in FIG. 1) or a single-layer structure (not shown), where each layer may include, for example, SiCN, SiO₂, SiNₓ, AlOₓN_{y}, a metal oxide (e.g, AlOₓ), Ru, W, Ti, Al, Co, CoWP, other suitable materials, or any combination thereof. In accordance with some embodiments, the metal trench 106 may include, for example, Cu, Ru, W, Ti, Al, Co, Mo, Ir, Rh, other suitable materials, or any combination thereof. The barrier layer 104 is disposed over the etch stop layer 102 to prevent metal atoms in the metal trench 106 from diffusing into an interlayer dielectric layer (not shown from the perspective of FIG. 1) in which the metal trench 106 is formed. In accordance with some embodiments, the barrier layer 104 may include, for example, Ru, W, Ti, Al, Co, Mo, Ir, Rh, any nitride of these metals, other suitable materials, or any combination thereof. The metal trench 106 is disposed over the barrier layer 104, and extends laterally (i.e., parallel to a top surface of the substrate 100) in a left-right direction from the perspective of FIG. 1. In accordance with some embodiments, the barrier film 104 may be omitted depending on a bulk metal used in the metal trench 106, and this disclosure is not limited in this respect.

In FIG. 1, the interconnection structure includes a first interconnection layer formed over the substrate 100, and a second interconnection layer formed over the first interconnection layer. The first interconnection layer includes an etch stop layer 108 formed over the substrate 100, an interlayer dielectric layer 110 formed over the etch stop layer 108, a plurality of metal trenches 118A, 118B formed through a top surface of the interlayer dielectric layer 110 (i.e., the metal trenches 118A, 118B being formed in the interlayer dielectric layer 110, with top surfaces of the metal trenches 118A, 118B being revealed from or coplanar with the top surface of the interlayer dielectric layer 110), and a metal via 114 connecting the metal trench 118B to the metal trench 106. In accordance with some embodiments, the interlayer dielectric layer 110 may include, for example, SiOₓC_{y}H_{z}, SiOₓ, SiCN, oxygen-doped carbide (ODC), nitrogen-doped carbide (NDC), tetraethoxysilane (TEOS) oxide, SiNₓ, other low-k materials, other suitable materials, or any combination thereof. The metal trenches 118A, 118B are spaced apart from each other laterally in the left-right direction, and extend laterally (i.e., parallel to the top surface of the substrate 100) in an inward-outward direction from the perspective of FIG. 1 (inward being into the page of FIG. 1). Specifically, the top surfaces of the metal trenches 118A, 118B are coplanar and are positioned at the same height relative to the top surface of the substrate 100. For each of the metal trenches 118A, which are not connected to metal vias in the illustrative section, a barrier layer 116 is formed between the metal trench 118A and the interlayer dielectric layer 110 to prevent metal atoms in the metal trench 118A from diffusing into the interlayer dielectric layer 110. For the same reason, a barrier layer 112 is formed between the metal trench 118B and the interlayer dielectric layer 110 and between the metal via 114 and the interlayer dielectric layer 110 to prevent metal atoms in the metal trench 118B and the metal via 114 from diffusing into the interlayer dielectric layer 110. In accordance with some embodiments, each of the barrier layers 112, 116 may include, for example, Ru, W, Ti, Al, Co, Mo, Ir, Rh, any nitride of these metals, other suitable materials, or any combination thereof. In the illustrative embodiment, the metal trenches 118A, 118B and the metal via 114 are fabricated using a dual damascene process, so the metal trench 118B and the metal via 114 are formed in one piece. In some embodiments, the metal trenches 118A, 118B and the metal via 114 may be fabricated using a single damascene process, and there may be a barrier layer formed between the metal trench 118B and the metal via 114, and this disclosure is not limited in this respect.

In the illustrative embodiment, a plurality of air gaps 120 are formed in the interlayer dielectric layer 110. The interlayer dielectric layer 110 can be divided into a top portion, a middle portion and a bottom portion, where the metal trenches 118A, 118B are formed in the top portion, the air gaps 120 are formed in the bottom portion, the middle portion is disposed between the top portion and the bottom portion, and the metal via 114 extends from the metal trench 118B, through the middle portion and the bottom portion of the interlayer dielectric layer 110 and the etch stop layer 108, and to the metal trench 106. In accordance with some embodiments, each of the metal trenches 118A, 118B may include, for example, Cu, Ru, W, Ti, Al, Co, Mo, Ir, Rh, other suitable materials, or any combination thereof. The air gaps 120 respectively correspond in position to the metal trenches 118A, are spaced apart from the metal trenches 118A vertically by the middle portion of the interlayer dielectric layer 110 in an up-down direction perpendicular to the top surface of the substrate 100 from the perspective of FIG. 1, and are spaced apart from the metal via 114 laterally in the left-right direction. In the illustrative embodiment, each of the metal trenches 118A is disposed over and overlaps the corresponding one of the air gaps 120 in the up-down direction, which means that a part of the metal trench 118A is aligned with a part of the corresponding air gap 120 in the up-down direction, but this disclosure is not limited in this respect. In accordance with some embodiments, some air gaps formed in the bottom portion of the interlayer dielectric layer 110 may not overlap with any of the metal trenches formed in the top portion of the interlayer dielectric layer 110. In accordance with some embodiments, each of the metal trenches 118A, 118B and the metal via 114 may have a thickness in a range from about 100 angstroms to about 600 angstroms, the etch stop layer 108 may have a thickness from about 1 angstrom to about 200 angstroms, and each of the air gaps 120 may have a thickness in a range from about 100 angstroms to about 500 angstroms. In accordance with some embodiments, a minimum pitch between adjacent metal trenches 118A, 118B may be in a range from about 12 nm to about 76 nm. In accordance with some embodiments, for each of the air gaps 120, a distance between the air gap 120 and the corresponding metal trench 118A in the up-down direction may be greater than about 50 angstroms to serve as a tolerance for etching of the interlayer dielectric layer 110. In accordance with some embodiments, for each of the air gaps 120, a distance between the air gap 120 and the metal via 114 in the left-right direction may range from about 50 angstroms to about 200 angstroms, so that an area of the air gap 120 is sufficiently large to effectively reduce the equivalent dielectric constant in the interlayer dielectric layer 110, while a tolerance for overlay misalignment between a pattern of the air gaps 120 and a pattern of the metal via 114 can be preserved.

The second interconnection layer includes an etch stop layer 122 formed over the first interconnection layer, an interlayer dielectric layer 124 formed over the etch stop layer 122, a metal trench 130 formed in the interlayer dielectric layer 124, and a metal via 128 connecting the metal trench 130 to the metal trench 118B. The metal trench 130 extends laterally (i.e., parallel to the top surface of the substrate 100) in the left-right direction from the perspective of FIG. 1. A barrier layer 126 is formed between the metal trench 130 and the interlayer dielectric layer 124 and between the metal via 128 and the interlayer dielectric layer 124 to prevent metal atoms in the metal trench 130 and the metal via 128 from diffusing into the interlayer dielectric layer 124. In accordance with some embodiments, each of the metal trench 130 and the metal via 128 may include, for example, Cu, Ru, W, Ti, Al, Co, Mo, Ir, Rh, other suitable materials, or any combination thereof. In accordance with some embodiments, the barrier layer 126 may include, for example, Ru, W, Ti, Al, Co, Mo, Ir, Rh, any nitride of these metals, other suitable materials, or any combination thereof.

In the illustrative embodiment, a plurality of air gaps 132 are formed in the interlayer dielectric layer 124. The metal trench 130 is formed in a top portion of the interlayer dielectric layer 124, the air gaps 132 are formed in a bottom portion of the interlayer dielectric layer 124, and the metal via 128 extends from the metal trench 130, through a middle portion and the bottom portion of the interlayer dielectric layer 124 and the etch stop layer 122, and to the metal trench 118B. The air gaps 132 are disposed under and overlap the metal trench 130 in the up-down direction, are spaced apart from the metal trench 130 vertically by the middle portion of the interlayer dielectric layer 124 in the up-down direction, and are spaced apart from the metal via 128 laterally in the left-right direction. In accordance with some embodiments, each of the metal trenches 130 and the metal via 128 may have a thickness in a range from about 100 angstroms to about 500 angstroms, the etch stop layer 122 may have a thickness from about 1 angstrom to about 200 angstroms, and each of the air gaps 132 may have a thickness in a range from about 100 angstroms to about 600 angstroms. In accordance with some embodiments, for each of the air gaps 132, a distance between the air gap 132 and the metal trench 130 in the up-down direction may be greater than about 50 angstroms to serve as a tolerance for etching of the interlayer dielectric layer 124. In accordance with some embodiments, for each of the air gaps 132, a distance between the air gap 132 and the metal via 128 may range from about 50 angstroms to about 200 angstroms, so that an area of the air gap 132 is sufficiently large to effectively reduce the equivalent dielectric constant in the interlayer dielectric layer 124, while a tolerance for overlay misalignment between a pattern of the air gaps 132 and a pattern of the metal via 128 can be preserved.

In practice, a single interlayer dielectric layer (e.g., the interlayer dielectric layer 110 or 124 in FIG. 1) may be formed to include a plurality of the abovementioned air gaps (i.e., being formed under metal trenches of the same layer, such as the air gaps 120 in the interlayer dielectric layer 110 or the air gaps 132 in the interlayer dielectric layer 124). In accordance with some embodiments, a local density of the air gaps in a single interlayer dielectric layer may range from about 10% to 60%, so that an equivalent dielectric constant in the interlayer dielectric layer is sufficiently low, while the interlayer dielectric layer has sufficient mechanical strength to prevent reliability degradation such as peeling or crashing of the interlayer dielectric layer. In accordance with some embodiments, the local density of the air gaps in a single interlayer dielectric layer may be referred to as, on a given plane that is parallel to the top surface of the substrate 100 and that intersects the air gaps in the interlayer dielectric layer, for a local area that conforms to a predetermined rule (e.g., a 1 μm×1 μm square area), a ratio of an area occupied by the air gaps over the entire area of the interlayer dielectric layer within the local area.

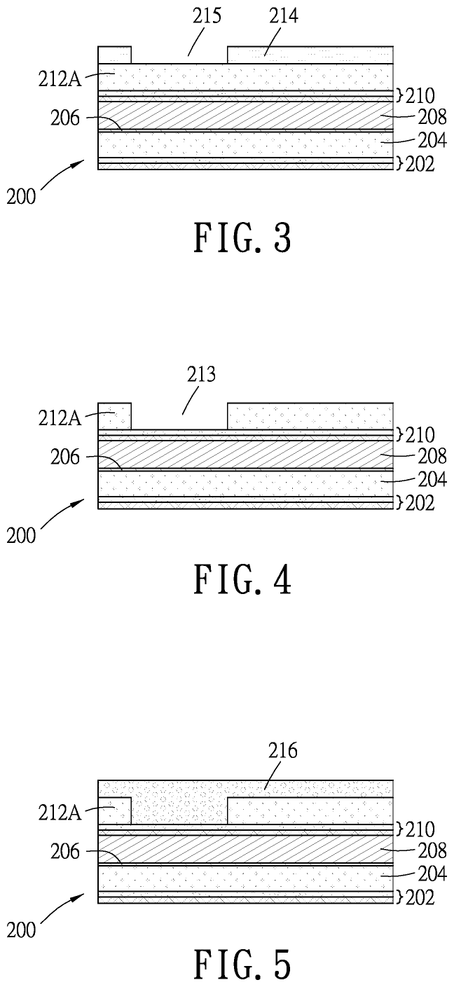

FIG. 2 is a flow chart that cooperates with FIGS. 3 to 13 to illustrate a method for fabricating an interconnection structure having an air gap which is formed under a metal trench in the same layer.

Referring to FIGS. 2 and 3, a semiconductor substrate 200 is provided to include an etch stop layer 202, an interlayer dielectric layer 204 formed over the etch stop layer 202, a barrier layer 206 formed over the interlayer dielectric layer 204, a metal trench 208 formed over the barrier layer 206 and in the interlayer dielectric layer 204, and an etch stop layer 210 formed over the metal trench 208 and the interlayer dielectric layer 204. Film deposition is performed (step S1) to deposit a dielectric film 212A over the etch stop layer 210, and a photoresist film 214 over the dielectric film 212A. The photoresist film 214 is then patterned by a lithography process that includes exposure and development to form an air-gap pattern therein. In accordance with some embodiments, the lithography process may be performed using extreme ultraviolet (EUV) lithography, immersion lithography, other suitable technologies, or any combination thereof, depending on sizes of air gaps to be formed. In the illustrative embodiment, the air-gap pattern formed in the photoresist film 214 includes a photoresist recess 215. To be specific, the air-gap pattern is designed in such a way that the photoresist recess 215 is misaligned with each metal via that is to be formed later in the dielectric film 212A. In accordance with some embodiments, the photoresist film 214 may be of either a single layer structure or a multi-layer structure that includes, for example, a bottom layer, a middle layer, and a photoresist layer. In accordance with some embodiments, each of the interlayer dielectric layer 204 and the dielectric film 212A may include, for example, SiOₓC_{y}H_{z}, SiOₓ, SiCN, ODC, NDC, TEOS oxide, SiNₓ, other low-k materials, other suitable materials, or any combination thereof, and may be formed using, for example, physical vapor deposition (PVD), chemical vapor deposition (CVD), other suitable techniques, or any combination thereof. In accordance with some embodiments, the metal trench 208 may include, for example, Cu, Ru, W, Ti, Al, Co, Mo, Ir, Rh, other suitable materials, or any combination thereof, and may be formed using, for example, PVD, CVD, electrochemical plating (ECP), atomic layer deposition (ALD), other suitable techniques, or any combination thereof. In accordance with some embodiments, the barrier layer 206 may include, for example, Ru, W, Ti, Al, Co, Mo, Ir, Rh, any nitride of these metals, other suitable materials, or any combination thereof, and may be formed using, for example, ALD, other suitable techniques, or any combination thereof. In accordance with some embodiments, the etch stop layers 202, 210 may include, for example, SiCN, SiO₂, SiNₓ, AlOₓN_{y}, metal oxide (e.g, AlOₓ), Ru, W, Ti, Al, Co, CoWP, other suitable materials, or any combination thereof, and may be formed using, for example, PVD, CVD, ALD, plasma-enhanced CVD (PECVD), other suitable techniques, or any combination thereof.

Referring to FIGS. 2 and 4, the dielectric film 212A is etched (step S2) with the patterned photoresist film 214 (see FIG. 3) serving as an etching mask, so as to transfer the air-gap pattern to the dielectric film 212A. The air-gap pattern formed in the dielectric film 212A includes a dielectric recess 213 that corresponds in position to the photoresist recess 215 (see FIG. 3) and that reveals the etch stop layer 210. In accordance with some embodiments, the etching of the dielectric film 212A may be performed using, for example, wet etching, dry etching, other suitable techniques, or any combination thereof.

Referring to FIGS. 2 and 5, a sacrificial polymer layer 216 is deposited (step S3) over the dielectric film 212A and in the dielectric recess 213 (see FIG. 4). In accordance with some embodiments, the sacrificial polymer layer 216 may be composed of, for example, elements of oxygen, carbon, nitrogen, other suitable elements, or any combination thereof. In some embodiments, the sacrificial polymer layer 216 may be made of polyurea which is obtained by reaction between di-isocyanate (e.g., 1,3-diisocyanatocyclohexane) and di-amine (e.g., 1,3-bis(aminomethyl)cyclohexane), but this disclosure is not limited in this respect, as long as the material that forms the sacrificial polymer layer 216 can be burned out under high temperature to form an air gap in subsequent processes. In accordance with some embodiments, the sacrificial polymer layer 216 may be deposited using, for example, spin-on deposition, CVD, conformal CVD, flowable CVD, other suitable techniques that have good gap-filling capabilities, or any combination thereof.

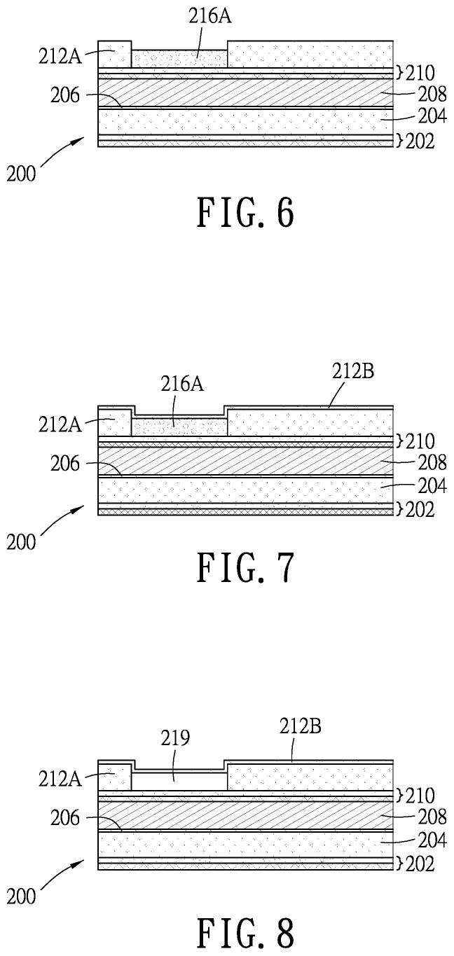

Further referring to FIG. 6, excessive portions of the sacrificial polymer layer 216 is removed (step S4), so that a top surface of the dielectric film 212A is revealed, and a remaining portion of the sacrificial polymer layer 216 in the dielectric recess 213 (see FIG. 4) forms a sacrificial polymer feature 216A. In accordance with some embodiments, the removal of the excessive portions of the sacrificial polymer layer 216 may be performed using, for example chemical-mechanical planarization (CMP), dry etching, other suitable techniques, or any combination thereof. When CMP is used in step S4 to remove the excessive portions of the sacrificial polymer layer 216, resultant top surfaces of the sacrificial polymer layer 216 and the dielectric film 212A may be coplanar and disposed at the same height relative to the top surface of the semiconductor substrate 200. When an etching technique is used in step S4, in order to ensure complete removal of the excessive portions of the dielectric film 212A that are outside of the dielectric recess 213, the sacrificial polymer layer 216 may be etched to an extent where a top surface of the sacrificial polymer feature 216A is slightly lower than the top surface of the dielectric film 212A relative to the top surface of the semiconductor substrate 200, as shown in FIG. 6.

FIGS. 7 to 10 illustrate a first way of forming an air gap (hereinafter referred to as a first implementation), and FIGS. 11 to 13 illustrate a second way of forming an air gap (hereinafter referred to as a second implementation). The first implementation is suitable for a case where a dielectric film that is to be formed over the air gap is non-porous (e.g., having a porosity smaller than 1%), and the second implementation is suitable for a case where a dielectric film that is to be formed over the air gap is porous (e.g., having a porosity greater than about 5%).

Referring to FIGS. 2 and 7, in the first implementation, a capping film 212B is deposited over the dielectric film 212A and the sacrificial polymer feature 216A (step S5). In the illustrative embodiment, the capping film 212B is conformal with the dielectric film 212A and the sacrificial polymer feature 216A, but this disclosure is not limited in this respect. In accordance with some embodiments, the capping film 212B may be porous so that the sacrificial polymer feature 216A can be burned out through the capping film 212B in subsequent high-temperature processes to form the air gap between the capping film 212B and the etch stop layer 210. In accordance with some embodiments, when the capping film 212B is very thin (e.g., at about 30 angstroms or thinner), the porosity of the capping film 212B can be smaller than 5%, even as small as 1%, and the capping film 212B is still capable of allowing the sacrificial polymer feature 216A to be burned out therethrough in subsequent high-temperature processes. In the illustrative embodiment as shown in FIG. 7, the capping film 212B is a sustaining layer that is used to sustain the existence of the air gap after removal of the sacrificial polymer layer 216A. In accordance with some embodiments, the capping film 212B may have a thickness in a range from about 10 angstroms to about 30 angstroms, so as to allow the sacrificial polymer feature 216A to be burned out therethrough while having sufficient strength to sustain the existence of the air gap. In accordance with some embodiments, the capping film 212B may include, for example, SiOₓC_{y}H_{z}, SiOₓ, SiCN, ODC, NDC, TEOS oxide, SiNₓ, other low-k materials, other suitable materials, or any combination thereof, and may be formed using, for example, PVD, CVD, ALD, other suitable techniques, or any combination thereof. Materials used in the capping film 212B may be either the same as or different from the materials used in the dielectric film 212A.

Referring to FIGS. 2 and 8, the sacrificial polymer feature 216A (see FIG. 7) is burned out (step S6) using, for example, a furnace, rapid thermal annealing (RTA), ultraviolet (UV), laser flash, other suitable techniques, or any combination thereof, at a temperature ranging from about 200° C. to about 450° C. for a period of time ranging from about 5 minutes to about 10 minutes. After the sacrificial polymer feature 216A is completely burned out, the air gap 219 that corresponds in position to the dielectric recess 213 (see FIG. 4) is formed between the capping film 212B and the etch stop layer 210, and the air gap 219 has a height (or thickness) equal to a distance between a top surface of the etch stop layer 210 and a bottom surface of the capping film 212B. In the illustrative embodiment, the air gap 219 is formed in both of a top surface and a bottom surface of the dielectric film 212A, namely, the air gap 219 extends through the dielectric film 212A in the up-down direction.

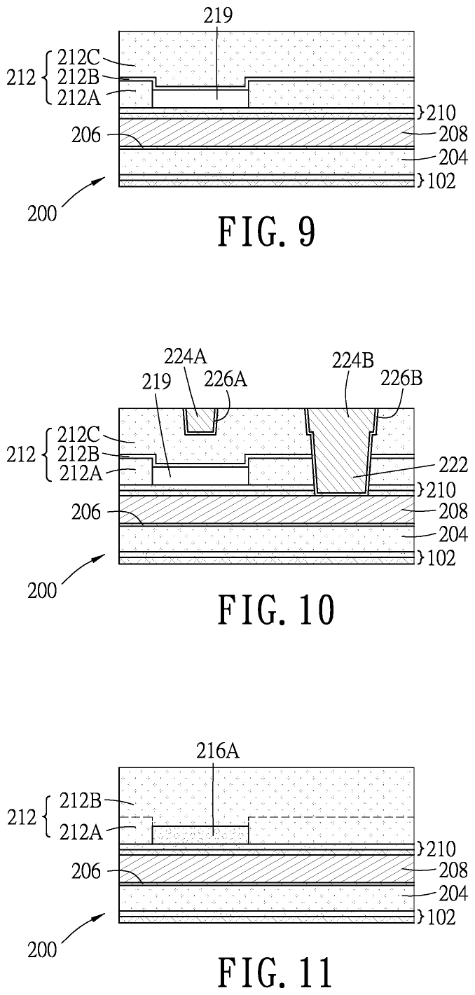

Further referring to FIG. 9, a dielectric film 212C is deposited over the capping film 212B, and the dielectric film 212C is separated from the air gap 219 by the capping film 212B. The dielectric film 212C may include, for example, SiOₓC_{y}H_{z}, SiOₓ, SiCN, ODC, NDC, TEOS oxide, SiNₓ, other low-k materials, other suitable materials, or any combination thereof, and may be formed using, for example, PVD, CVD, other suitable techniques, or any combination thereof. In accordance with some embodiments, the dielectric film 212C may be either porous or non-porous. In accordance with some embodiments, for any two of the dielectric film 212A, the capping film 212B and the dielectric film 212C, they may be made of either the same material(s) or chemical composition(s) or different materials or chemical compositions, have either the same porosity or different porosities, and this disclosure is not limited in this respect. The porosities of the dielectric films may be controlled by adjusting process parameters or factors, such as temperature, pressure, gas flow rate, post-deposition treatment, other suitable process parameters or factors, or any combination thereof. The dielectric film 212A, the capping film 212B and the dielectric film 212C cooperate to form an interlayer dielectric layer 212.

Referring to FIGS. 2 and 10, a metal trench 224A is formed (step S7) over the air gap 219 and in the dielectric film 212C (so the dielectric film 212C may be thicker than the metal trench 224A) using a damascene process, with a barrier layer 226A being formed between the metal trench 224A and the dielectric film 212C. In the damascene process, a metal via 222 and a metal trench 224B are formed in the interlayer dielectric layer 212 as well, where the metal trench 224B is spaced apart from the metal trench 224A laterally, the metal via 222 is spaced apart from the air gap 219 laterally and extends from the metal trench 224B, through the interlayer dielectric layer 212 and the etch stop layer 210, and to the metal trench 208, and a barrier layer 226B is formed between the metal trench 224B and the dielectric film 212C and between the metal via 222 and the interlayer dielectric layer 212. In accordance with some embodiments, the metal trenches 224A, 224B and the metal via 222 may include, for example, Cu, Ru, W, Ti, Al, Co, Mo, Ir, Rh, other suitable materials, or any combination thereof, and may be formed using, for example, PVD, CVD, ECP, ALD, other suitable techniques, or any combination thereof. In accordance with some embodiments, the barrier layers 226A, 226B may include, for example, Ru, W, Ti, Al, Co, Mo, Ir, Rh, any nitride of these metals, other suitable materials, or any combination thereof, and may be formed using, for example, ALD, other suitable techniques, or any combination thereof. Because the metallization process is performed after formation of the air gap 219, the processes that form the air gap 219 would not cause any damage to the metal trenches 224A, 224B and the metal via 222. On the other hand, although the air gap 219 is formed prior to the metallization process, the interlayer dielectric layer 212 provides good structural support that prevents the interconnection structure from collapsing during the metallization process due to the air gap 219.

Referring to FIGS. 2 and 11, in the second implementation, a capping film 212B is deposited over the dielectric film 212A and the sacrificial polymer feature 216A (step S5). In the illustrative embodiment, the capping film 212B is a porous dielectric film, so that the sacrificial polymer feature 216A can be burned out through the capping film 212B in subsequent high temperature processes to form the air gap between the capping film 212B and the etch stop layer 210. In accordance with some embodiments, the capping film 212B may be made highly porous (e.g., having a porosity greater than or equal to about 10%), so that the following burning-out process can be performed more smoothly and more efficiently. In accordance with some embodiments, the capping film 212B may include, for example, SiOₓC_{y}H_{z}, SiOₓ, SiCN, ODC, NDC, TEOS oxide, SiNₓ, other low-k materials, other suitable materials, or any combination thereof, and may be formed using, for example, spin-on deposition, CVD, conformal CVD, flowable CVD, other suitable techniques that have good gap-filling capabilities, or any combination thereof. Materials used in the capping film 212B may be either the same as or different from the materials used in the dielectric film 212A. The dielectric film 212A and the capping film 212B cooperate to form an interlayer dielectric layer 212.

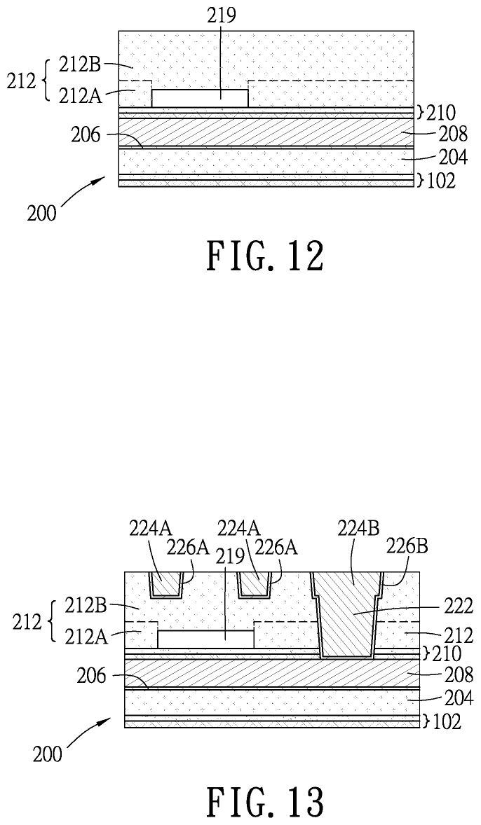

Referring to FIGS. 2 and 12, the sacrificial polymer feature 216A (see FIG. 11) is burned out (step S6) using, for example, a furnace, RTA, UV, laser flash, other suitable techniques, or any combination thereof, at a temperature ranging from about 200° C. to about 450° C. for a period of time ranging from about 5 minutes to about 10 minutes. After the sacrificial polymer feature 216A is completely burned out, the air gap 219 that corresponds in position to the dielectric recess 213 (see FIG. 4) is formed between the capping film 212B and the etch stop layer 210, and the air gap 219 has a height (or thickness) equal to a distance between a top surface of the etch stop layer 210 and a bottom surface of the capping film 212B. In the illustrative embodiment, the air gap 219 is formed in both of a top surface and a bottom surface of the dielectric film 212A, namely, the air gap 219 extends through the dielectric film 212A in the up-down direction.

Referring to FIGS. 2 and 13, metal trenches 224A are formed (step S7) over the air gap 219 and in the capping film 212B (so the capping film 212B may be thicker than the metal trenches 224A) using a damascene process. For each of the metal trenches 224A, a barrier layer 226A is formed between the metal trench 224A and the capping film 212B. In the damascene process, a metal via 222 and a metal trench 224B are formed in the interlayer dielectric layer 212 as well, where the metal trench 224B is spaced apart from the metal trenches 224A laterally, the metal via 222 is spaced apart from the air gap 219 laterally and extends from the metal trench 224B, through the interlayer dielectric layer 212 and the etch stop layer 210, and to the metal trench 208, and a barrier layer 226B is formed between the metal trench 224B and the capping film 212B and between the metal via 222 and the interlayer dielectric layer 212. Because the metallization process is performed after formation of the air gap 219, the processes that form the air gap 219 would not cause any damage to the metal trenches 224A, 224B and the metal via 222. On the other hand, although the air gap 219 is formed prior to the metallization process, the interlayer dielectric layer 212 provides good structural support that prevents the interconnection structure from collapsing during the metallization process due to the air gap 219.

In accordance with some embodiments, an interconnection structure is provided to include a semiconductor substrate, an interlayer dielectric that is disposed over the semiconductor substrate and that is formed with an air gap, and a first metal trench that is formed in the interlayer dielectric layer, and that is disposed over the air gap.

In accordance with some embodiments, the interconnection structure further includes a second metal trench and a metal via. The second metal trench is formed in the interlayer dielectric layer, and is spaced apart from the first metal trench laterally. The metal via is formed in the interlayer dielectric layer, and extends from the second metal trench to the semiconductor substrate. The air gap is spaced apart from the metal via laterally.

In accordance with some embodiments, the first metal trench is formed in a top portion of the interlayer dielectric layer, and the air gap is formed in a bottom portion of the interlayer dielectric layer.

In accordance with some embodiments, the interlayer dielectric layer has a first portion which is porous and in which the first metal trench is formed.

In accordance with some embodiments, the interlayer dielectric layer has a second portion which is different from the first portion in terms of material and in which the air gap is formed.

In accordance with some embodiments, the interlayer dielectric layer has a second portion which is different from the first portion in terms of porosity and in which the air gap is formed.

In accordance with some embodiments, the interlayer dielectric layer has a first body portion which is non-porous and in which the first metal trench is formed, and a film portion which is more porous than the first body portion and which separates the first body portion from the air gap.

In accordance with some embodiments, the interlayer dielectric layer further has a second body portion, the air gap is formed in a top surface of the second body portion, and the film portion is disposed over the air gap and the second body portion.

In accordance with some embodiments, an interconnection structure is provided to include a semiconductor substrate, an interlayer dielectric layer disposed over the semiconductor substrate, and a first metal trench. The interlayer dielectric layer has a bottom portion formed with an air gap, a middle portion disposed over the bottom portion, and a top portion disposed over the middle portion. The first metal trench is formed in the top portion of the interlayer dielectric layer. The middle portion of the interlayer dielectric layer separates the air gap from the top portion of the interlayer dielectric layer.

In accordance with some embodiments, the first metal trench overlaps the air gap in a direction perpendicular to a top surface of the semiconductor substrate.

In accordance with some embodiments, the interconnection structure further includes a second metal trench and a metal via. The second metal trench is formed in the top portion of the interlayer dielectric layer, and is spaced apart from the first metal trench. The metal via is formed in the interlayer dielectric layer, and extends from the second metal trench, through the interlayer dielectric layer, and to the semiconductor substrate. The air gap is spaced apart from the metal via.

In accordance with some embodiments, the top portion and the middle portion of the interlayer dielectric layer are porous.

In accordance with some embodiments, the bottom portion of the interlayer dielectric layer is different from the top portion of the interlayer dielectric layer in terms of material.

In accordance with some embodiments, the bottom portion of the interlayer dielectric layer is different from the top portion of the interlayer dielectric layer in terms of porosity.

In accordance with some embodiments, the top portion of the interlayer dielectric layer is non-porous, and the middle portion of the interlayer dielectric layer is more porous than the top portion of the interlayer dielectric layer.

In accordance with some embodiments, the air gap is formed in a top surface of the bottom portion of the interlayer dielectric layer.

In accordance with some embodiments, a method is provided for fabricating an interconnection structure. In one step, a first dielectric film is formed over a semiconductor substrate. In one step, a first recess is formed in the first dielectric film. In one step, a sacrificial feature is formed in the first recess. In one step, a capping film is formed over the first dielectric film and the sacrificial feature. In one step, the sacrificial feature is burned out through the capping film to form an air gap. In one step, a metal trench is formed over the air gap.

In accordance with some embodiments, in one step, a second dielectric film is formed over the capping film. The metal trench is formed in the second dielectric film.

In accordance with some embodiments, the capping film is more porous than the second dielectric film.

In accordance with some embodiments, the capping film is porous and is thicker than the metal trench, and the metal trench is formed in the capping film.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An interconnection structure, comprising:
a semiconductor substrate;
an interlayer dielectric layer that is disposed over the semiconductor substrate, and that is formed with an air gap; and
a first metal trench that is formed in the interlayer dielectric layer, and that is disposed over the air gap.

2. The interconnection structure according to claim 1, further comprising:
a second metal trench that is formed in the interlayer dielectric layer, and that is spaced apart from the first metal trench laterally; and
a metal via that is formed in the interlayer dielectric layer, and that extends from the second metal trench to the semiconductor substrate;
wherein the air gap is spaced apart from the metal via laterally.

3. The interconnection structure according to claim 1, wherein the first metal trench is formed in a top portion of the interlayer dielectric layer, and the air gap is formed in a bottom portion of the interlayer dielectric layer.

4. The interconnection structure according to claim 1, wherein the interlayer dielectric layer has a first portion which is porous and in which the first metal trench is formed.

5. The interconnection structure according to claim 4, wherein the interlayer dielectric layer has a second portion which is different from the first portion in terms of material and in which the air gap is formed.

6. The interconnection structure according to claim 4, wherein the interlayer dielectric layer has a second portion which is different from the first portion in terms of porosity and in which the air gap is formed.

7. The interconnection structure according to claim 1, wherein the interlayer dielectric layer has a first body portion which is non-porous and in which the first metal trench is formed, and a film portion which is more porous than the first body portion and which separates the first body portion from the air gap.

8. The interconnection structure according to claim 7, wherein the interlayer dielectric layer further has a second body portion, the air gap is formed in a top surface of the second body portion, and the film portion is disposed over the air gap and the second body portion.

9. An interconnection structure, comprising:
a semiconductor substrate;
an interlayer dielectric layer that is disposed over the semiconductor substrate, and that has a bottom portion formed with an air gap, a middle portion disposed over the bottom portion, and a top portion disposed over the middle portion; and
a first metal trench that is formed in the top portion of the interlayer dielectric layer;
wherein the middle portion of the interlayer dielectric layer separates the air gap from the top portion of the interlayer dielectric layer.

10. The interconnection structure according to claim 9, wherein the first metal trench overlaps the air gap in a direction perpendicular to a top surface of the semiconductor substrate.

11. The interconnection structure according to claim 10, further comprising:
a second metal trench that is formed in the top portion of the interlayer dielectric layer, and that is spaced apart from the first metal trench; and
a metal via that is formed in the interlayer dielectric layer, and that extends from the second metal trench, through the interlayer dielectric layer, and to the semiconductor substrate;
wherein the air gap is spaced apart from the metal via.

12. The interconnection structure according to claim 9, wherein the top portion and the middle portion of the interlayer dielectric layer are porous.

13. The interconnection structure according to claim 12, wherein the bottom portion of the interlayer dielectric layer is different from the top portion of the interlayer dielectric layer in terms of material.

14. The interconnection structure according to claim 12, wherein the bottom portion of the interlayer dielectric layer is different from the top portion of the interlayer dielectric layer in terms of porosity.

15. The interconnection structure according to claim 9, wherein the top portion of the interlayer dielectric layer is non-porous, and the middle portion of the interlayer dielectric layer is more porous than the top portion of the interlayer dielectric layer.

16. The interconnection structure according to claim 15, wherein the air gap is formed in a top surface of the bottom portion of the interlayer dielectric layer.

17. A method for fabricating an interconnection structure, comprising:
forming a first dielectric film over a semiconductor substrate;
forming a first recess in the first dielectric film;
forming a sacrificial feature in the first recess;
forming a capping film over the first dielectric film and the sacrificial feature;
burning out the sacrificial feature through the capping film to form an air gap; and
forming a metal trench over the air gap.

18. The method according to claim 17, further comprising:
forming a second dielectric film over the capping film,
wherein the metal trench is formed in the second dielectric film.

19. The method according to claim 18, wherein the capping film is more porous than the second dielectric film.

20. The method according to claim 17, wherein the capping film is porous and is thicker than the metal trench, and the metal trench is formed in the capping film.
